(19) United States
(12) Patent Application Publication
(10) Pub. No.: US 2012/0315742 A1
(43) Pub. Date: Dec. 13, 2012

(54) METHOD FOR FORMING NITRIDE SEMICONDUCTOR DEVICE

(75) Inventors: Keiichi YUI, Yokohama-shi (JP); Ken NAKATA, Yokohama-shi (JP); Isao MAKABE, Yokohama-shi (JP); Tsuyoshi KOUCHI, Yokohama-shi (JP)

(73) Assignee: SUMITOMO ELECTRIC INDUSTRIES, LTD., Osaka-shi (JP)

(21) Appl. No.: 13/489,647

(22) Filed: Jun. 6, 2012

(30) Foreign Application Priority Data
Jun. 8, 2011 (JP) 2011-128648
Jun. 8, 2011 (JP) 2011-128649

(51) Int. Cl. H01L 21/20

(52) U.S. Cl. 438/478; 257/E21.097

(57) ABSTRACT

A method for producing a nitride semiconductor device is disclosed. The method includes steps of: forming a channel layer, an InAlN doped layer sequentially on the substrate, raising a temperature of the substrate as supplying a gas source containing In, and/or another gas source containing Al, and growing GaN layer on the InAlN doped. Or, the method grows the channel layer, the InAlN layer, and another GaN layer sequentially on the substrate, raising the temperature of the substrate, and growing the GaN layer. These methods suppress the sublimation of InN from the InAlN layer.

### BACKGROUND OF THE INVENTION

1. Field of the Invention

The present invention relates to a semiconductor device, in particular, one embodiment of the semiconductor device is, what is called, the high-electron mobility transistor (HEMT) made of nitride semiconductor materials.

2. Related Prior Arts

Nitride semiconductor materials have been applicable to a power device showing a high output in higher frequencies. One prior art has disclosed a HEMT that includes a buffer layer, GaN carrier transit layer, which is often called as a channel layer, AlGaN carrier supplying layer, which is often called as a doped layer, each sequentially grown on a substrate, and utilizes a two dimensional electron gas (2DEG) formed in the channel layer at an interface against the doped.

Conventional HEMT devices use the spontaneous polarization and the piezo polarization to induce 2DEG in the channel layer. In order to induce 2DEG with higher carrier concentration, the Al composition in AlGaN doped layer is necessary to be increased. However, such an AlGaN material inherently shows a large lattice mismatching against GaN channel layer, which degrades the quality of 2DEG and resultantly the performance of the HEMT device.

Another type of the doped layer made of InAlN has been investigated because InAlN in the lattice constant thereof matches with GaN channel layer in a wide range of the compositions. Moreover, the InAlN material shows a large difference in the spontaneous polarization and a large discontinuity in the conduction band with respect to GaN channel layer, which may theoretically create 2DEG with the sheet carrier concentration of 2×10¹³ cm⁻².

However, an InAlN layer grown in a high temperature often shows a degraded quality with many In vacancies because, when a material containing In is exposed in a high temperature, indium is first sublimated compared with aluminum (Al) and nitrogen (N). Moreover, when the device has the InAlN doped layer as the topmost layer, the long term reliability of the device is degraded because InAlN layer contains aluminum (Al) likely to be oxidized when it is exposed to the air, and an aluminum oxide, typically Al₂O₃, is induced on the surface of InAlN doped layer. Such an extra material may affect the band structure of the device.

### SUMMARY OF THE INVENTION

An aspect of one embodiment of the present application relates to a method to form a semiconductor device. The method includes steps of: growing a channel layer made of nitride semiconductor material; growing an InAlN layer epitaxially on the channel layer at a first temperature; raising a temperature of the substrate from the first temperature to a second temperature as supplying a gas source containing indium (In); and growing a second GaN layer epitaxially of the InAlN layer at the second temperature higher than the first temperature.

A feature of the method to form the nitride semiconductor device is that the InAlN layer, which operates as a doped layer, is may be grown in a relatively lower temperature of the first temperature, while, the GaN layer, which operates as a cap layer, may be grown at the second temperature higher than the first temperature to secure the quality of the grown layer; and a gas containing In is continuously supplied during a period to raise the temperature. Because the surface of the InAlN layer is exposed in an atmosphere containing In, the sublimation of InN, which may degrade the crystal quality of the InAlN layer, may be effectively suppressed. In one modification, the surface of the InAlN layer may be exposed in an atmosphere containing In and aluminum (Al), under which the sublimation of not only InN but AlN may be effectively suppressed.

Another aspect of one embodiment of the present application also relates to a method to form a nitride semiconductor device. The other method includes a step of, instead of setting the atmosphere containing In and/or Al, growing another GaN layer epitaxially on the InAlN layer before raising the temperature of the substrate, raising the temperature as covering the surface of the InAlN layer by the other GaN layer, and growing the GaN layer on the other GaN layer at the second temperature higher than a temperature under which the other GaN layer is grown.

Because the surface of the InAlN layer, which is grown at the first temperature lower than the second temperature, may be covered by the other GaN layer, the sublimation of InN, and/or AlN, from the surface of the InAlN layer may be effectively suppressed even the temperature of the substrate is set in the second temperature higher than the first temperature.

### BRIEF DESCRIPTION OF THE DRAWINGS

The invention may be more completely understood in consideration of the following detailed description of various embodiments of the invention in connection with the accompanying drawings, in which:

FIG. 1 shows a stack of semiconductor layers according to an embodiment of the present invention;

FIG. 2 shows a sequence of the temperature and the as sources to grow respective layers shown in FIG. 1;

FIG. 3A shows the oxygen profile in InAlN doped layer measured from a top surface thereof, FIG. 3B shows the oxygen profile in InAlN doped layer and GaN cap layer measured from the top surface of GaN cap layer, and FIG. 3C shows the oxygen profile in InAlN doped layer and GaN cap layer when GaN cap layer is grown at a relatively lower temperature within ±100° C. with respect to the temperature to grown InAlN doped layer;

FIG. 4 shows a cross section of a nitride semiconductor device having the stack of semiconductor layers shown in FIG. 1;

FIG. 5 shows a sequence of the temperature and the gas sources to grow the stack shown in FIG. 1 according to the second embodiment;

FIG. 6 shows another stack of semiconductor layers according to the third embodiment of the invention;

FIG. 7 shows a sequence of the temperature to grow the stack shown in FIG. 6;

FIG. 8 shows a carbon profile within InAlN doped layer, the first GaN cap layer, and the second GaN cap layer measured from the top surface of the second GaN layer; and

FIG. 9 schematically shows a mechanism to lower the threading dislocations appeared in the surface of the second GaN layer.

### DESCRIPTION OF EMBODIMENTS

Next, some embodiments according to the present invention will be described as referring to accompanying drawings.

### First Embodiment

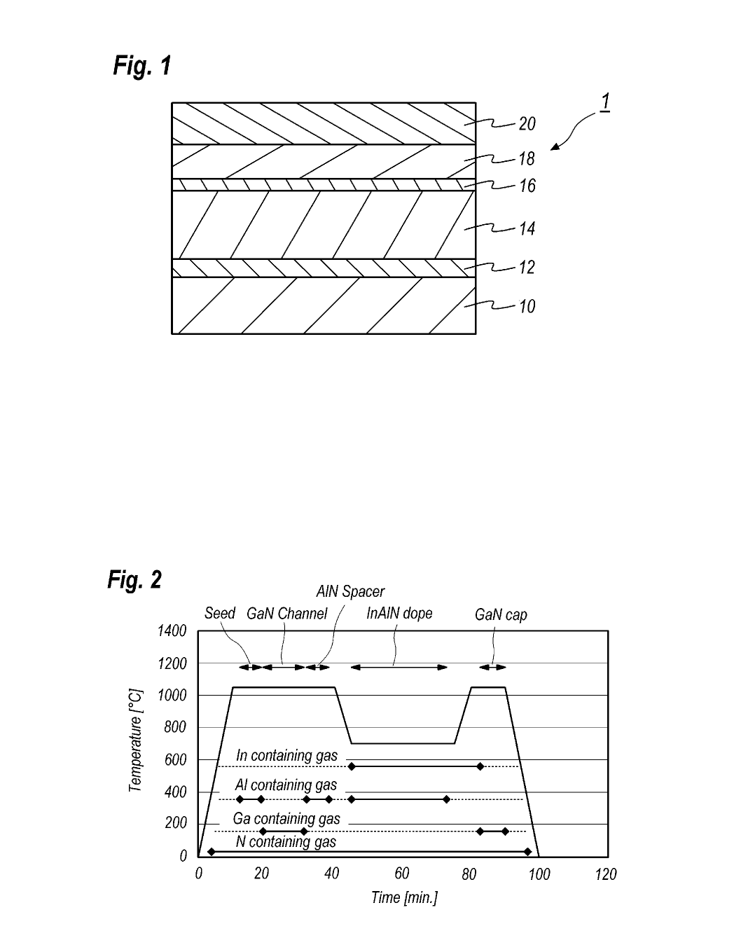

FIG. 1 shows a cross section of a stack of semiconductor layers applicable to a nitride semiconductor device, and FIG. 2 shows a sequence of a temperature and source materials for the growth of the semiconductor layers shown in FIG. 1. The growth of the semiconductor layers is carried out by the well-known technique of the metal-organized-chemical-vapor-deposition (MOCVD). Referring to FIGS. 1 and 2, the process first sets a substrate 10 made of SiC within a furnace of the MOCVD and converts the interior of the furnace into hydrogen (H) atmosphere. Then, raising the substrate 10 to 1050° C., the process grows a seed layer 12 made of AlN by supplying tri-methyl-aluminum (TMA) and ammonia (NH₃) into the growth furnace. A thickness of AlN seed layer 12 may be, for instance, 20 nm.

Then, keeping the temperature of the substrate 10 in 1050° C., the process grows a channel layer 14 made of GaN on AlN seed layer 12 by supplying tri-methyl-gallium (TMG) and ammonia into the furnace. The GaN channel layer 14 may have a thickness of, for instance, 1 μm. Then, keeping the temperature of the substrate 10 also in 1050° C., the process grows a spacer layer 16 made of AlN by changing the source materials to TMA and NH₃ with a thickness of, for instance, 1 nm. Subsequently, falling the temperature of the substrate 10 down to 700° C., a doped layer 18 made of InAlN is grown on AlN spacer layer 16 by supplying source gasses of TMI, TMA, and NH₃. The thickness of InAlN doped layer is only, for instance, 5 nm.

Then, raising the temperature of the substrate 10 up to 1050° C. as supplying TMI and ammonia to keep the furnace in an atmosphere primarily containing indium (In) and ammonia. Setting the pressure within the furnace in an ordinary condition, the atmosphere primarily containing In and ammonia may suppress the sublimation of InN from irregular growth of InN on InAlN doped layer 18.

Stabilizing the temperature of the substrate 10 at 1050° C., the process changes the source gas from TMI to a mixture of TMG with ammonia, and grows a cap layer 20 made of GaN on InAlN doped layer 18. The GaN cap layer 20 may have a thickness of, for instance, 5 nm. Thus, the stack of semiconductor layers shown in FIG. 1 may be completed. Table 1 below listed summarizes the conditions to grow respective layers, 12 to 20.

TABLE 1
Conditions for growing layers

| Layer | source | T(° C.) | t(nm) |
|---|---|---|---|
| AlN seed layer 12 | TMA, NH₃ | 1050 | 20 |
| GaN channel layer 14 | TMG, NH₃ | 1050 | 1000 |
| AlN spacer layer 16 | TMA, NH₃ | 1050 | 1 |
| InAlN doped layer 18 | TMI, TMA, NH₃ | 700 | 5 |
| In composition: 17% | | | |
| GaN cap layer 20 | TMG, NH₃ | 1050 | 5 |

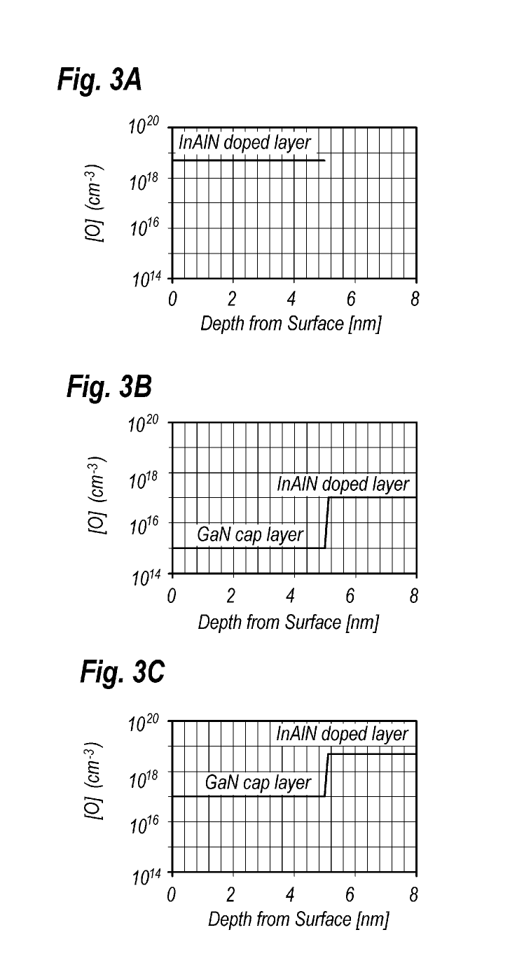

The MOCVD generally accompanies with the capture of oxygen (O) contained in the source gases within a grown layer. FIG. 3A schematically shows the profile of the oxygen concentration [0] in InAlN doped layer 18 at the completion of the growth of InAlN doped layer 18, FIG. 3B shows the oxygen profile in GaN cap layer 20 and InAlN doped layer 18 at the completion of the growth of GaN cap layer 20. While, FIG. 3C shows a oxygen profile from a surface of GaN cap layer 20 to InAlN doped layer 18 when GaN cap layer 20 is grown on InAlN doped layer 18 at a temperature within ±100° C. with respect to the growth temperature of InAlN doped layer 18, which is lower than the growth temperature of the case shown in FIG. 3B.

Referring to FIG. 3A, the oxygen concentration in InAlN doped layer 18 at the completion of the growth reaches 7×10¹⁸ cm⁻³, which is relatively high. This is because InAlN doped layer 18 contains aluminum (Al), and aluminum (Al) may accelerate the capture of oxygen (O). Moreover, the growth of InAlN doped layer 18 is carried out in a relatively lower temperature, which suppresses the desorption of captured oxygen therefrom. Referring to FIG. 3B, growing GaN cap layer on InAlN doped layer 18 at 1050° C., which is relatively higher temperature, oxygen (O) captured in InAlN doped layer 18 may diffuse into the grown GaN cap layer 20, and at the completion of the growth of GaN cap layer 20, the oxygen concentration in InAlN doped layer 18 decreases about two digits to an amount of 1×10¹⁷ cm⁻³. Moreover, the growth of GaN cap layer 20 carried out at higher temperature may reduce the oxygen concentration thereat to 1×10¹⁵ cm⁻³ due to the desorption therefrom.

On the other hand, in a case where GaN cap layer 20 is grown at relatively lower temperature compared with that shown in FIG. 3B, namely, within a range of ±100° C. with respect to the growth temperature of InAlN doped layer 18, oxygen captured in InAlN doped layer 19 is hard to diffuse thermally and the final oxygen concentration thereat may be left in substantially unchanged, and the oxygen concentration in GaN cap layer does not decrease to be left in an amount around 1×10¹⁷ cm⁻³, as shown FIG. 3C.

Thus, although InAlN doped layer 18 is likely to capture oxygen therein but the captured oxygen may diffuse during the growth of GaN cap layer 20 at a higher temperature, which decreases the oxygen concentration in InAlN doped layer 18. The MOCVD growth is known that a growing semiconductor layers is likely to capture not only oxygen but carbon (C). Accordingly, the growth of GaN cap layer 20 on InAlN doped layer may diffuse not only oxygen but carbon (C) within the growing GaN cap layer 20, and may decrease the carbon concentration in InAlN doped layer.

The mechanism above described concentrates a condition where oxygen, and/or carbon, captured in InAlN doped layer 18 primarily diffuse into GaN cap layer 20. However, the thermal diffusion of atoms is an isotropic mechanism. Oxygen and/or carbon captured in InAlN doped layer 18 may diffuse into AlN spacer layer 16, or into GaN channel layer 14 through AlN spacer layer 20. However, AlN spacer layer 20 may operate as a diffusion barrier for oxygen and/or carbon. Accordingly, the thermal diffusion of oxygen and/or carbon during the growth of GaN cap layer 20 heads for the grown GaN cap layer 20.

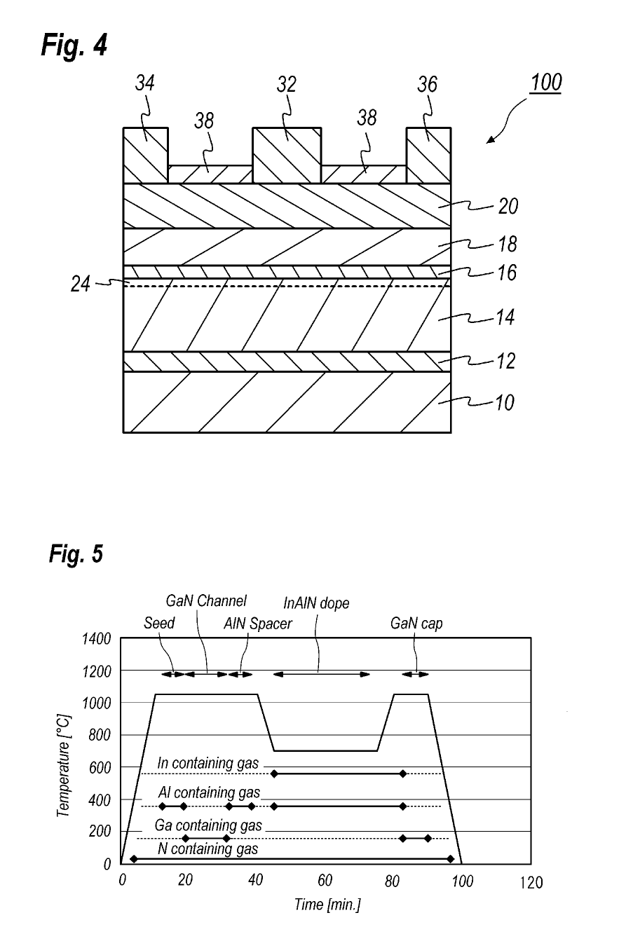

FIG. 4 shows a cross section of a semiconductor device 100 having the semiconductor stack shown in FIG. 1. The device 100 provides gate, source, and drain electrodes, 32 to 36, respectively, on GaN cap layer 20. The insulating layer 38, which may be made of, for instance, silicon nitride (SiN) may cover surfaces of GaN cap layer 20 exposed between electrodes, 32 to 36. The gate electrode 32 may be a stacked metal of nickel (Ni) and gold (Au), while, the source and drain electrodes, 34 and 36, are also a stacked metal of titanium (Ti) and aluminum (Al), where nickel (Ni) and titanium (Ti) are in contact with GaN cap layer 20.

The device 100 shown FIG. 4 has a structure of, what is called, the HEMT (High Electron Mobility Transistor) with the SiC substrate 10, AlN seed layer 12 with a thickness of 20 nm, GaN channel layer 14 with a thickness of 1 μm, AlN spacer layer 16 with a thickness of 1 nm, InAlN doped layer 18 with a thickness of 5 nm and an In composition of 17%, where this InAlN doped layer 18 lattice-matches with GaN, and GaN cap layer 20 with a thickness of 5 nm. Electrons supplied from InAlN doped layer 18 may cause the 2DEG 24 in GaN channel layer 14 at the interface against AlN spacer layer 16. Electrons running in the 2DEG between the source and drain electrodes, 34 and 36, are modulated by a bias applied to the gate electrode 32, thus, the device 100 shows an amplifying function.

The gate, source, and drain electrodes, 32 to 36, may be formed by a conventional process of the metal evaporation with the subsequent lift-off technique. The insulating layer 38 may be also formed by a conventional technique, for instance, the plasma-enhanced chemical vapor deposition (p-CVD).

The first embodiment according to the present invention is thus described. That is, InAlN doped layer 18 may be grown on AlN spacer layer 16 at a relatively lower temperature, and the temperature of the substrate 10 is raised after the completion of the growth of InAlN doped layer 18. A feature of the process according to an embodiment is that, during the increase of the temperature, the process keeps the inside of the furnace in an atmosphere containing indium (In) by supplying a gas containing indium, and the GaN cap layer 20 is grown on InAlN doped layer 18 after the temperature reaches the preset condition. The atmosphere containing indium may suppress the sublimation of InN from the surface of InAlN doped layer 18, which may suppress the degradation of the quality of InAlN doped layer 18.

The embodiment thus described assumes that the supply of gas containing In during the rise of the furnace temperature is kept substantially constant; however, the supply of In-contained gas is preferable to increase as the temperature rises, because, the sublimation of InN from InAlN doped layer is accelerated as the temperature thereof rises. Accordingly, In-contained gas is preferably increased as the temperature rises to suppress the sublimation of InN effectively. One example is that TMI is supplied at a rate of 35 μmol/min during the growth of InAlN doped layer 18, then, the rate thereof is lowered to 10 μmol/min at the beginning, while, it is increased to 50 μmol/min at the completion of the increase of the temperature.

The rate to increase the supply of In-contained gas may be varied linearly, stepwise, or according to a function monotonically increase.

As described in FIGS. 3A to 3C, GaN cap layer 20 grown at a higher temperature may effectively decrease the oxygen and/or carbon concentration in InAlN doped layer, which may results in InAlN doped layer 18 having a preferable quality. When the GaN cap layer 20, in particular, portions of GaN cap layer 20 beneath respective electrodes, 32 to 36, has a high oxygen, and/or carbon concentration, the performance of the device would be degraded. The GaN cap layer 20 grown at a high temperature may reduce the oxygen, and/or carbon concentration. Thus, GaN cap layer 20 is preferable to be grown at a higher temperature, for instance, higher than 900° C., or further preferably higher than 1000° C., or 1050° C. as that of an embodiment. While, the growth temperature of GaN cap layer 20 is preferably lower than 1100° C. from a view point to suppress hillocks caused in the surface of the grown layer.

On the other hand, the growth temperature of InAlN doped layer 18 is preferably in a range of 600 to 800° C. An InAlN doped layer 18 grown in a higher temperature may cause the sublimation of primarily indium (In), which makes the quality of the grown crystal poor. A growth temperature of 600 to 800° C. may suppress the sublimation of 1n, and result in a grown InAlN layer with excellent qualification.

The embodiment above described continues to supply a gas containing indium during the period for raising the temperature. However, the process may temporarily cease the supply of the In-containing gas after the completion of the growth of InAlN layer 18, and resume the supply as the temperature increases.

As shown in FIG. 2, it is preferable to continue the supply of the In-containing gas for a period after the temperature reaches the preset condition. The GaN cap layer 20 is preferably grown after this period passes in order to stable the temperature, accordingly, the gas containing In is preferably supplied during this period until the temperature becomes stable in the preset condition to suppress the sublimation of InN.

### Second Embodiment

Another embodiment of the invention will be described as referring to FIG. 5. The process according to the second embodiment may supply the gas containing not only indium (In) but aluminum (Al) for the period to raise the temperature of the substrate 10. The semiconductor stack applicable to the second embodiment is the same as those shown in FIG. 1. Specifically, the process may grow semiconductor layers from AlN seed layer 12 to AlN spacer layer 16 shown in FIG. 1 on SiC substrate 10 by setting the temperature of SiC substrate 10 to be 1050° C. The conditions to grow those layers are the same as those of the first embodiment.

Then, the process lowers the temperature down to 700° C. and grows InAlN doped layer 18 under the conditions same as those of the aforementioned embodiment. Continuing the supply of TMI and TMA within the furnace, the process raises the temperature of SiC substrate up to 1050° C. The supply not only TMI but TMA during the rise of the temperature may effectively suppress not only the sublimation of InN and AlN but also excess growth of InAlN on InAlN doped layer 18.

Reaching the temperature of the substrate 10 to be 1050° C., the process ceases the supply of TMI and TMA, while, supplies TMG and NH₃ in the furnace to grow GaN cap layer 20. Thus, the stack of semiconductor layers, 12 to 18, is sequentially grown on SiC substrate 10.

The process according to the second embodiment supplies not only a gas containing In but another gas containing Al during the period to raise the temperature of the substrate 10 after the growth of InAlN doped layer 18. When the substrate 10 in a temperature thereof becomes relatively high, not only InN but AlN sublimate from the surface of InAlN doped layer 18. Supplying a gas containing both In and Al during the period to raise the temperature of the substrate 10, the sublimation of InN and AlN from InAlN doped layer 18 may be effectively suppressed.

The gas containing both In and Al may be evenly supplied during the period. However, the supply thereof may be gradually increased as the temperature of the substrate 10 is raised because the sublimation of In and Al depends on the temperature. For instance, the process according to the second embodiment may supply TMI and TMA in the rates of 10 μmol/min and 5 μmol/min at the beginning, respectively; while, the rate is increased to be 50 μmol/min and 7 mmol/min at the end of the period to raise the temperature. Moreover, respective supply rates of the gas may be increased linearly, stepwise, and so on.

Similar to the aforementioned embodiment, the gas forming an atmosphere containing In and Al within the furnace may be ceased at the completion of the growth of InAlN doped layer 18 and is resumed during the period to raise the temperature, because the supply rate of the gas during the period to raise the temperature is different form those during the growth. A sequence is preferable where the gas is ceased once after the growth of InAlN doped layer, adjusted the rate thereof, and resumed during the period to raise the temperature. Furthermore, the supply of the gas to form the atmosphere containing In and Al may be left for a moment after the temperature of the substrate 10 reaches the preset condition until the growth conditions for GaN cap layer 20 becomes stable, as shown in FIG. 5.

The semiconductor device 100 shown in FIG. 4 has a plane surface of GaN cap layer 20. However, a device with a recessed gate electrode, and/or recessed ohmic electrodes may be considered. Further, InAlN doped layer 18 has the In composition of 17% lattice-matched to that of GaN. However, the doped layer 18 may have another arrangement of the In composition. For instance, the In composition of 12 to 35% may be applicable, and the In composition of 17 to 18% is preferable, where InAlN with those In composition substantially matches with the lattice constant thereof with that of GaN. While, the In composition less than 12% or greater than 35% causes cracks in a grown layer because of large lattice-mismatching along the crystal orientation of “a”.

The GaN cap layer 20 may be i-type or n-type. A GaN layer with the n-type conduction may be further stable compared with GaN with i-type conduction because of the compensation of the surface charges. Moreover, a GaN grown on a high temperature may enhance the activation of dopants, which further compensates the surface charges and makes the energy band structure of GaN cap layer. The process may use silane (SiH₄) as the n-type dopants.

Although the embodiments above described applies SiC to the substrate 10. However, the device may use other types of substrates, such as silicon (Si), GaN, sapphire (Al₂O₃), gallium oxide (Ga₂O₃), and so on. The process may also apply other types of source gasses, for instance, tri-ethyl-aluminum (TEA) for aluminum, tri-ethyl-gallium (TEG) for gallium, and so on. Still further, AlN spacer layer 16 may be replaced by Al_{γ}Ga_{1-γ}N (0<=y<=1), and GaN channel layer 14 may be replaced by a nitride compound material generally denoted by B_{α}Al_{β}Ga_{γ}In_{1-α-β-γ}N, where compositions α, β, and γ satisfy a relation of:

2.55α+3.11β+3 3.19γ+3.55×(1-α-β-γ)=3.55x+3.11(1−x),

where the nitride compound defined by the equation above lattice-matches with another nitride compound of where the composition x is between 0.17 and 0.18 to match the lattice constant thereof with that of GaN.

The embodiments above described concentrates on InAlN doped layer and the process to raise the temperature as supplying a gas containing In or, In and Al. However, the spirit of the invention may be applicable to another system where the temperature of the substrate is raised from a relatively lower temperature to a higher temperature exceeding 900° C. as exposing the surface of InAlN. By supplying a gas containing In or, In and Al during the period to raise the temperature, the sublimation of InN, and/or AlN, may be effectively suppressed to obtain an excellent surface of InAlN.

### Third Embodiment

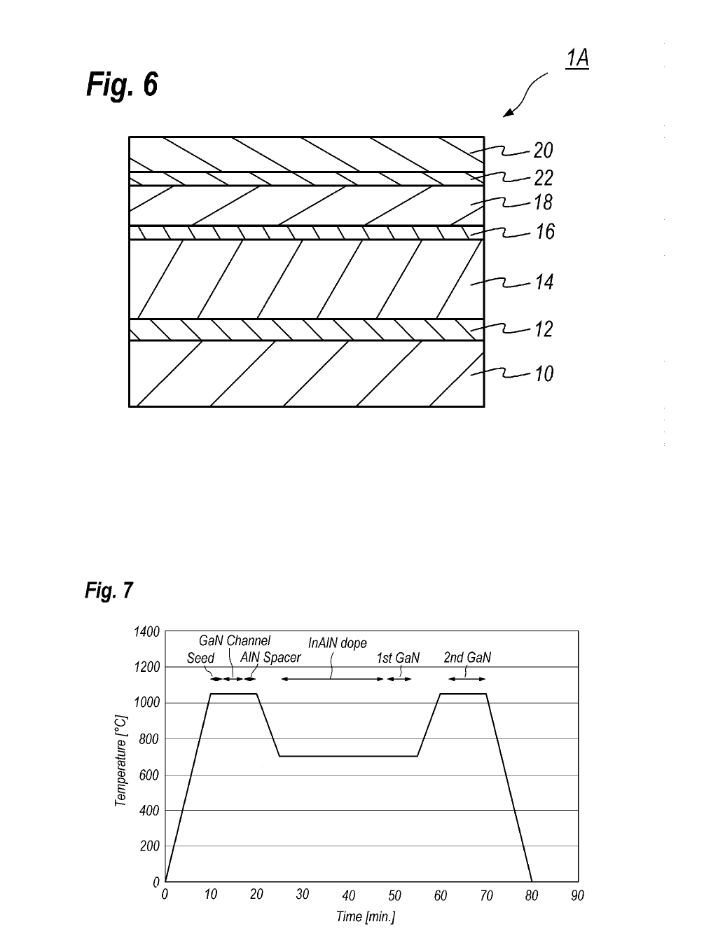

Still another embodiment according to the present invention will be described as referring to FIG. 6 which shows a cross section of another stack of semiconductor layers according to the third embodiment of the invention. The stack 1A, shown in FIG. 6 has a feature distinguishable from that shown in FIG. 1 in a point that the stack 1A, includes another GaN layer 22 between InAlN doped layer 17 and GaN layer 20. The original GaN cap layer 20 is hereinafter called as the second GaN layer 20, while, additional GaN layer 22 is called as the first GaN layer 22.

Table 2 below listed summarizes conditions to grow respective layers 12-22 shown in FIG. 6; while FIG. 7 shows a procedure to grow the layers 12-22. Another feature according to the present embodiment is that the conditions to grow two GaN layers, 20 and 22, that is, the present method grows the first GaN layer 22 immediately on InAlN doped layer 18 at a relatively lower temperature of 700° C., which is same with that for InAlN doped layer 18. Then, the second GaN layer 20 is grown on the first GaN layer 22 after the temperature of the substrate 10 is raised to 1050° C. During the period to raise the temperature, the surface of InAlN doped layer 18 may be covered by the first GaN layer 22, which may effectively suppress the sublimation of InN, and/or AlN, from the surface of InAlN doped layer 18.

TABLE 2
Growth conditions for respective layers

| Layer | source | T(° C.) | t(nm) |
|---|---|---|---|
| AlN seed layer 12 | TMA, NH₃ | 1050 | 20 |
| GaN channel layer 14 | TMG, NH₃ | 1050 | 1000 |
| AlN spacer layer 16 | TMA, NH₃ | 1050 | 1 |
| InAlN doped layer 18 | TMI, TMA, NH₃ | 700 | 5 |
| In composition: 17% | | | |
| First GaN layer 22 | TMG, NH₃ | 700 | 15 |
| Second GaN layer 20 | TMG, NH₃ | 1050 | 4 |

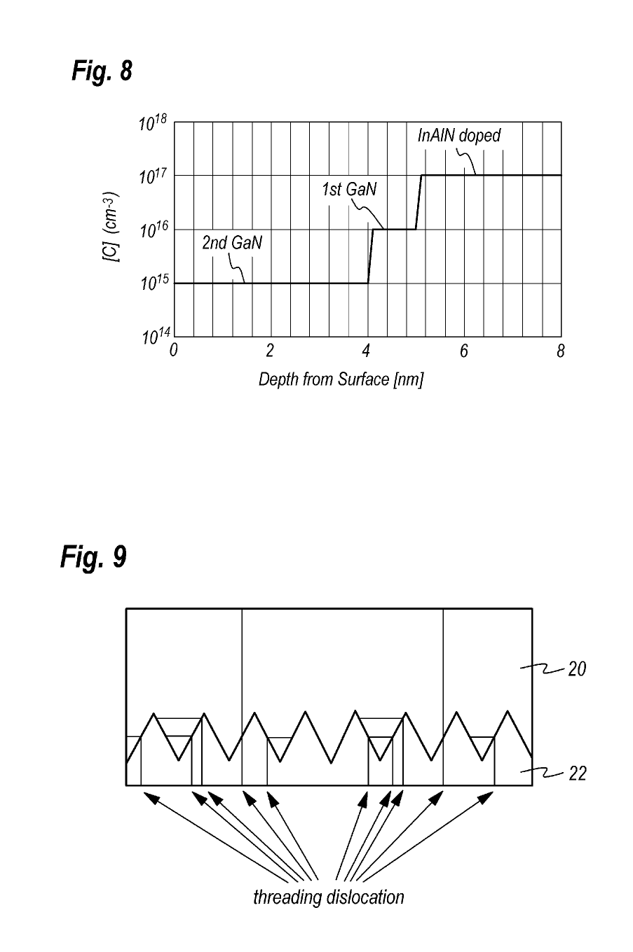

Similar to the arrangement of the semiconductor layers, 12 to 20, of the aforementioned embodiment, the process should take the capture of carbon during the growth of InAlN doped layer 18 into account. FIG. 8 schematically shows a carbon profile from the top of the first GaN layer 22 to InAlN doped layer 18 at the completion of the growth of the second GaN layer 20. The carbon concentration [C] monotonically decreases from InAlN doped layer 18 to the second GaN layer 20 whose surface shows the carbon concentration of around 1×10¹⁵ cm⁻³, while, InAlN doped layer 18 shows the highest carbon concentration [C] of 1×10¹⁷ cm⁻³, which is two digits greater than that in the second GaN layer 20. The process of the present embodiment grows InAlN doped layer 18 and the first GaN layer 22 at 700° C., where the captured carbon are hard to be desorbed in such a low temperature. Then, the process raises the temperature of the substrate 10 from 700° C. to 1050° C.; then grows the second GaN layer 20. The captured carbon in InAlN doped layer 18 and those in the first GaN layer 22 may thermally diffuse into the first GaN layer 22 and the second GaN layer 20, respectively, during the growth of the second GaN layer 20. Thus, as shown in FIG. 8, the carbon concentration [C] in InAlN doped layer 18 becomes highest, that in the second GaN layer 20 is lowest, and that in the first GaN layer 22 becomes intermediate.

Similarly, the MOCVD process often accompanies with the capture of, not only carbon, but oxygen during the growth of a layer. The oxygen concentration [0] in InAlN doped layer 18 and that in the first GaN layer 22 are around 5×10¹⁹ cm⁻³ and about 1×10¹⁷ cm⁻³ at the end of the growth of the first GaN layer 22. Because aluminum (Al) contained in InAlN doped layer 18 may accelerate the capture of carbon, the oxygen concentration [O] in InAlN doped layer 18 becomes higher than that in the first GaN layer 22. During the growth of the second GaN layer 20 at the temperature of 1050° C., the oxygen in InAlN doped layer 18 and those in the first GaN layer 22 may thermally diffuse into the first GaN layer 22 and the second GaN layer 20, respectively, to decrease the oxygen concentration [O] in layers, 18 and 22, to around 1×10¹⁷ cm⁻³ and around 1×10¹⁶ cm⁻³, respectively; while, that in the second GaN layer 20 stays in 1×10¹⁵ cm⁻³ even at the completion of the growth of the second GaN layer 20.

Thus, the process to form a nitride semiconductor device may lower the carbon concentration [C] and the oxygen concentration [O] in InAlN doped layer 18 and that in the first GaN layer 22, both of which are grown at 700° C. by diffusing them therefrom into the second GaN layer 20 during the growth of the second GaN layer 20 at a relatively high temperature of 1050° C. For instance, the process according to an embodiment may lower the carbon concentration in InAlN doped layer less than 1×10¹⁷ cm⁻³. The captured carbon and oxygen are primarily diffused into the second GaN layer 20, while it is hard to invade into GaN channel layer 14 because of the existence of AlN spacer layer 16.

The stack of the semiconductor layers, 12 to 22, shown in FIG. 6 may also constitute the nitride semiconductor device by forming the gate, source, and drain electrodes, 32 to 36, on the second GaN layer 20. The device may further provide the insulating layer 38 between the electrodes where the second GaN layer 20 is exposed.

When the second GaN layer 20 contains carbon, and/or oxygen, in a substantial concentration, the device having such GaN layer 20 often shows degraded performances. The device according to the present embodiment provides the second GaN layer 20 grown at a temperature higher than that for the first GaN layer 22, the carbon concentration, and/or the oxygen concentration in the first and second GaN layers, 22 and 20, may be effectively reduced to sustain the device performance.

FIG. 9 schematically shows a cross section of the first and second GaN layers, 22 and 20, taken by the transmission electron microscope (TEM). The surface of the first GaN layer 22 shows unevenness, or some bumps, because the first GaN layer 22 is grown at a lower temperature. Growing the second GaN layer 20 on the bumpy surface of the first GaN layer 22 at a higher temperature, threading dislocations due to the poor quality of the first GaN layer 22, which runs vertically, are perturbed to run horizontally at the interface against the second GaN layer 20, which decreases the number of dislocations reaching the surface of the second GaN layer 20. In an example, the threading dislocations running vertically in the first GaN layer 22 reaches, or sometimes exceeds 1×10⁹ cm⁻² in a density thereof at the completion of the growth of the first GaN layer 22; while, the density of the dislocations at the end of growth of the second GaN layer 20 decreases to 5×10⁷ cm⁻², which is far less than that in the first GaN layer 22.

In the process thus described, the first GaN layer 22 grown directly on InAlN layer 18 at 700° C. is preferably left on the surface of InAlN doped layer 18 just before the growth of the second GaN layer 20. In other words, the first GaN layer 22 is preferably sublimated at a rate of 0.05 nm/sec under a temperature from 1000 to 1080° C., which is typically applied to grow a GaN layer. Accordingly, assuming the period to raise the temperature of the substrate is t seconds, the first GaN layer 22 preferably has a thickness T:

T>=0.05×t[nm],

which secures that the first GaN layer 22 may cover the surface of InAlN doped layer 18 even immediate before the growth of the second GaN layer 20 to suppress the sublimation of InN from the surface of InAlN doped layer 18.

On the other hand, the first GaN layer 22 is likely to capture the carbon and oxygen during the growth thereof because of the first GaN layer 22 is grown at a relatively lower temperature as already described. Accordingly, the first GaN layer 22 is thinner as possible, preferably less than 1 nm. Such a thinner first GaN layer 22 may effectively suppress the degradation of the device performances. Assuming the period to raise the temperature of the substrate 10 after the growth of the first GaN layer 22 is t seconds as that assumed before, the first GaN layer 22 preferably has a thickness T:

T<=0.05×t+1[nm],

which secures the device performances. Taking the conditions described above, the thickness T of the first GaN layer 22 is preferably in a range of:

0.05×t<=T<=0.05×t+1[nm].

Although the embodiments thus described sets the growth temperature for the first GaN layer 22 is same with that for InAlN doped layer 18, the growth temperature for the first GaN layer 22 may be different from that for InAlN doped layer 18. A subject of the embodiments is that the second GaN layer 20 is grown at a temperature higher than that for InAlN doped layer 18, and that for the first GaN layer 22. However, when a growth temperature for the first GaN layer 22 is unnecessarily high, InAlN doped layer 18 sublimates InN from the surface thereof. Accordingly, the first GaN layer 22 is preferably grown at a temperature within 50° C. higher than the growth temperature for InAlN doped layer 18, or further preferably, within 25° C. higher than the growth temperature for InAlN doped layer 18. Considering a condition where InAlN doped layer 18 is grown at relatively lower temperature of 600 to 800° C., the first GaN layer 22 is preferably grown at a temperature higher than 600° C. to suppress the carbon and oxygen concentrations thereat, for instance, less than 1×10¹⁷ cm⁻³.

The embodiments described above, the second GaN layer 20 is grown at the temperature of 1050° C., the present invention is not restricted to this condition. It is preferable for the second GaN layer 20 to be grown at a temperature high enough to diffuse carbon and oxygen captured in InAlN doped layer 18 and the first GaN layer 22 during the growth of the second GaN layer 20 to decrease the carbon and oxygen concentrations. So the growth temperature for the second GaN layer 20 is necessary to be higher than 900° C., preferably higher than 1000° C., or further preferably higher than 1050° C.; but lower than 1100° C. for preventing surface damages such as hillocks.

Although the embodiments above described concentrate on the doped layer 18 made of InAlN, the doped layer 18 may be made of at least including InAlN. Or, the subject of the present invention may be applicable to a system that includes InAlN layer, a GaN layer grown on InAlN layer, and another GaN layer grown on the former GaN layer grown at a temperature higher than the temperature for growing the former GaN layer. As far as a stack of semiconductor layers has those arrangements, the sublimation of InN from the surface of InAlN layer to suppress the degradation of the quality thereof, and the carbon and oxygen concentrations in InAlN layer and the former GaN layer may be lowered.

While several embodiments and variations of the present invention are described in detail herein, it should be apparent that the disclosure and teachings of the present invention will suggest many alternative designs to those skilled in the art.

We claim:

1. A method for forming a semiconductor device, comprising steps of:
growing a channel layer epitaxially on a substrate, the channel layer being made of nitride semiconductor material;
growing an InAlN layer epitaxially on the channel layer at a first temperature;
raising a temperature of the substrate from the first temperature to a second temperature as supplying a gas source containing indium (In); and
growing a second GaN layer epitaxially on the InAlN layer at the second temperature.

2. The method of claim 1,
wherein the gas source containing In is one of tri-methyl-indium (TMI) and tri-ethyl-indium (TEI).

3. The method of claim 1,
wherein the step of raising the temperature of the substrate increases a supply rate of the gas source containing In.

4. The method of claim 1,
wherein the step of raising the temperature of the substrate is carried out as supplying another gas source containing aluminum (Al).

5. The method of claim 4,
wherein the other gas source containing Al is one of tri-methyl-aluminum (TMA) and tri-ethyl-aluminum (TEA).

6. The method of claim 4,
wherein the step of raising the temperature of the substrate increases a supply rate of the gas source containing In and the other gas source containing Al.

7. The method of claim 1,
wherein the second temperature is higher than 900° C.

8. The method of claim 1,
wherein the first temperature is higher than, or equal to, 600° C. but lower than, or equal to, 800° C.

9. The method of claim 1,
wherein the step of growing the channel layer includes a step of growing GaN.

10. The method of claim 1,
further including a step of growing AlN layer on the channel layer before the step of growing the InAlN doped layer.

11. The method of claim 10,
wherein the AlN layer has a thickness thinner than 1 nm.

12. The method of claim 1,
further including a step of, before growing the InAlN layer but after growing the channel layer, falling the temperature of the substrate down to the first temperature.

13. A method of forming a semiconductor device, comprising:
growing a channel layer epitaxially on a substrate, the channel layer being made of nitride semiconductor material;
growing an InAlN layer epitaxially on the channel layer at a first temperature;
growing a first GaN layer epeitaxially on the InAlN layer at a temperature within 50° C. higher than the first temperature;
raising a temperature of the substrate to a second temperature from the temperature for growing the first GaN layer; and
growing a second GaN layer epitaxially on the first GaN layer at the second temperature.

14. The method of claim 13,
wherein the first GaN layer is grown by a thickness T in a unit of nano-meter defined by:
0.05×t<=T<=0.05×t+1,
where t is a period to raise the temperature of the substrate to the second temperature from the temperature for growing the first GaN layer.

15. The method of claim 13,
wherein the first GaN layer is grown at a temperature within 100° C. lower than the first temperature.

16. The method of claim 13,
wherein the second GaN layer is grown at the second temperature higher than 900° C.

17. The method of claim 13,
further including a step of, before growing the InAlN layer, growing an AlN layer epitaxially on the channel layer by a thickness less than 1 nm.

18. The method of claim 13,
wherein the channel layer is made of GaN.

19. The method of claim 13,
further including a step of, after growing the channel layer but before growing the InAlN layer, falling a temperature of the substrate down to the first temperature.
